(19) United States
(12) Patent Application Publication
(10) Pub. No.: US 2026/0123482 A1
(43) Pub. Date: Apr. 30, 2026

(54) STACKED SUBSTRATE STRUCTURE AND MANUFACTURING METHOD THEREOF

(71) Applicant: Industrial Technology Research Institute, Hsinchu (TW)

(72) Inventors: Wei-Lan Chiu, Kaohsiung City (TW); Hsiang-Hung Chang, Hsinchu County (TW); Shih-Hsien Wu, Taoyuan City (TW); Yu-Wei Huang, Chiayi City (TW)

(73) Assignee: Industrial Technology Research Institute, Hsinchu (TW)

(21) Appl. No.: 19/062,068

(22) Filed: Feb. 25, 2025

(30) Foreign Application Priority Data
Oct. 30, 2024 (TW) 113141438

(51) Int. Cl. H01L 23/538; H01L 21/18; H01L 21/48; H01L 21/683; H01L 23/00; H01L 23/367; H01L 23/498; H01L 23/522; H01L 23/60; H01L 25/16

(52) U.S. Cl. CPC H10W 70/65; H10P 10/128; H10P 72/74; H10W 20/496; H10W 20/497; H10W 70/05; H10W 70/611; H10W 70/69; H10W 90/00; H10W 90/401; H10W 40/226; H10W 42/60; H10W 74/10; H10W 90/288; H10W 90/724

(57) ABSTRACT

A stacked substrate structure and a manufacturing method thereof are provided. The stacked substrate structure includes a first structure and a second structure. The first structure has a first bonding surface and includes a first circuit structure. The first circuit structure includes a plurality of first conductive layers and a first expansion modulation layer. The plurality of first conductive layers are stacked in a vertical direction. The first expansion modulation layer is disposed between the adjacent first conductive layers. A coefficient of thermal expansion of the first expansion modulation layer is greater than a coefficient of thermal expansion of the plurality of first conductive layers. The second structure has a second bonding surface, and the second bonding surface of the second structure faces the first bonding surface of the first structure.

### CROSS-REFERENCE TO RELATED APPLICATION

This application claims the priority benefit of Taiwan application serial no. 113141438, filed on Oct. 30, 2024. The entirety of the above-mentioned patent application is hereby incorporated by reference herein and made a part of this specification.

### TECHNICAL FIELD

The disclosure relates to a substrate structure and a manufacturing method thereof, and particularly relates to a stacked substrate structure and a manufacturing method thereof.

### BACKGROUND

As the demands for multi-function and fast computing speed in electronic products grow, chip packaging has gradually turned to three-dimensional (3D) stacking or 2.5-dimensional (2.5D) packaging development within a limited two-dimensional (2D) space. Moreover, in order to transmit more signals and maintain a high-speed and high-frequency transmission speed, it is necessary to increase the density of circuit layout and shorten the transmission distance between chips as much as possible. However, at present, the manufacturing process of the packaging structure that satisfies the above demands is complicated, and the yield is unsatisfying.

### SUMMARY

The disclosure provides a stacked substrate structure including a first structure and a second structure. The first structure has a first bonding surface. The first structure includes a first circuit structure. The first circuit structure includes a plurality of first conductive layers and a first expansion modulation layer. The plurality of first conductive layers are stacked in a vertical direction. The first expansion modulation layer is disposed between the plurality of adjacent first conductive layers. A coefficient of thermal expansion of the first expansion modulation layer is greater than a coefficient of thermal expansion of the plurality of first conductive layers. The second structure has a second bonding surface. The second bonding surface of the second structure faces the first bonding surface of the first structure.

The disclosure further provides a manufacturing method of a stacked substrate structure, and the method includes the following steps. A first structure is provided. The first structure has a first bonding surface. The first structure includes a plurality of first conductive layers and a first expansion modulation layer. The plurality of first conductive layers are stacked in a vertical direction. The first expansion modulation layer is disposed between the plurality of adjacent first conductive layers. A coefficient of thermal expansion of the first expansion modulation layer is greater than a coefficient of thermal expansion of the plurality of first conductive layers. A second structure is provided. The second structure has a second bonding surface, and the second structure includes a second bonding pad layer located on the second bonding surface. The first structure and the second structure are bonded through a thermal compression bonding process. A first bonding pad layer and the second bonding pad layer are in direct contact and are connected.

Several exemplary embodiments accompanied with figures are described in detail below to further describe the disclosure in details.

### BRIEF DESCRIPTION OF THE DRAWINGS

The accompanying drawings are included to provide a further understanding, and are incorporated in and constitute a part of this specification. The drawings illustrate exemplary embodiments and, together with the description, serve to explain the principles of the disclosure.

FIG. 1 is a schematic cross-sectional view of a stacked substrate structure according to an embodiment of the disclosure.

FIG. 2A to FIG. 2E are partially enlarged schematic cross-sectional views of a stacked substrate structure according to an embodiment of the disclosure.

FIG. 3A to FIG. 3C are partially enlarged schematic cross-sectional views of a stacked substrate structure according to an embodiment of the disclosure.

FIG. 4A is a partial schematic three-dimensional view of a stacked substrate structure according to an embodiment of the disclosure.

FIG. 4B is a schematic top view of FIG. 4A.

FIG. 5A is a partial schematic three-dimensional view of a stacked substrate structure according to another embodiment of the disclosure.

FIG. 5B is a schematic top view of FIG. 5A.

FIG. 6A is a partial schematic three-dimensional view of a stacked substrate structure according to another embodiment of the disclosure.

FIG. 6B is a schematic top view of FIG. 6A.

FIG. 7A is a schematic cross-sectional view of a stacked substrate structure according to an embodiment of the disclosure.

FIG. 7B is a partial schematic three-dimensional view of the stacked substrate structure according to an embodiment of the disclosure.

FIG. 8A, FIG. 8B, FIG. 8C, FIG. 8D, FIG. 8E, FIG. 8F, FIG. 8G, FIG. 8H, FIG. 8I, FIG. 8J, FIG. 8K, FIG. 8L, FIG. 8M, FIG. 8N, FIG. 8O, FIG. 8P, FIG. 8Q, FIG. 8R, FIG. 8R′, and FIG. 8S are schematic cross-sectional views of a manufacturing process of a stacked substrate structure according to an embodiment of the disclosure.

FIG. 9 is a schematic cross-sectional view of a stacked substrate structure according to an embodiment of the disclosure.

### DETAILED DESCRIPTION OF DISCLOSURED EMBODIMENTS

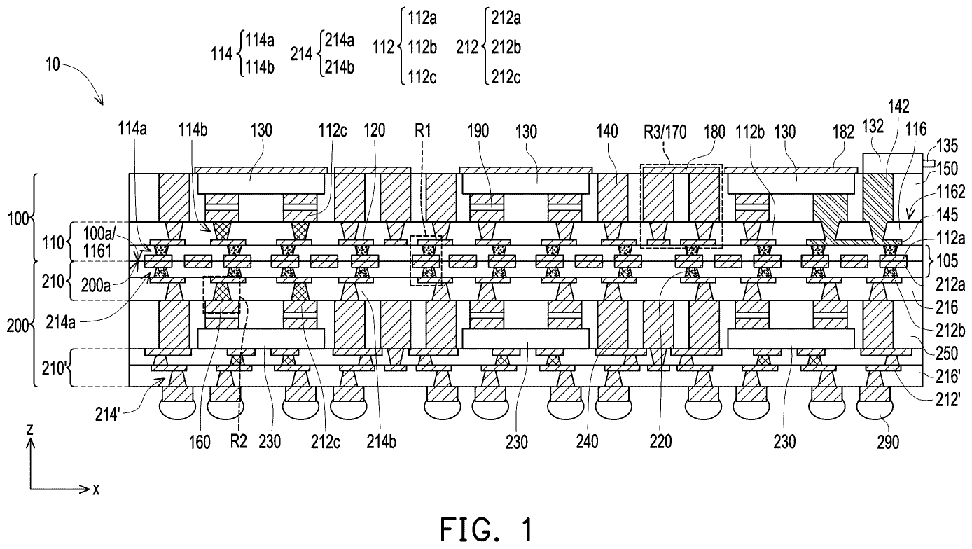

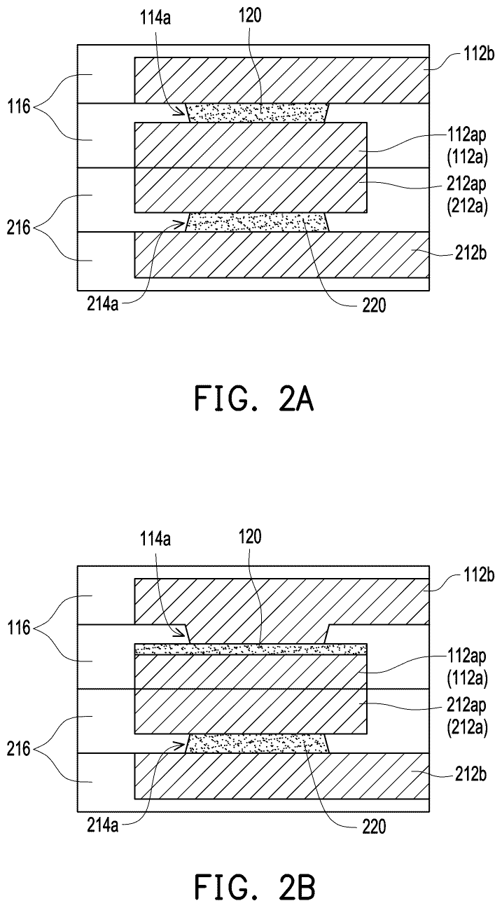

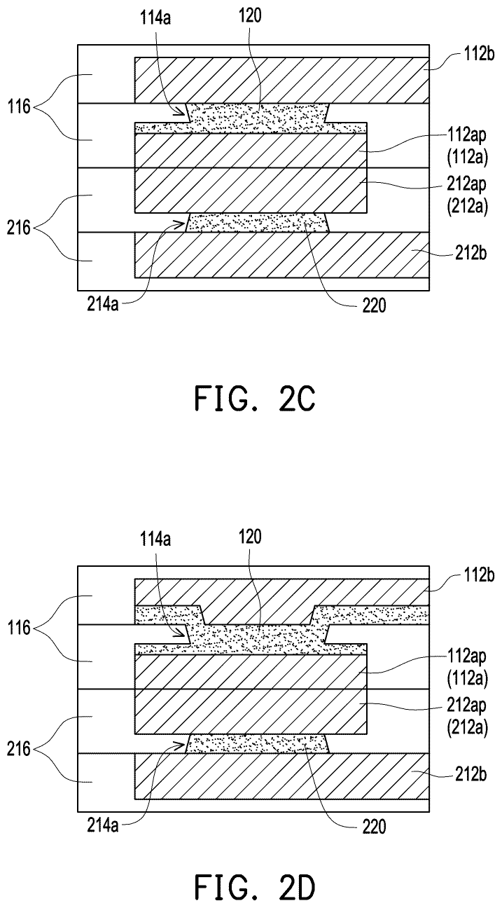

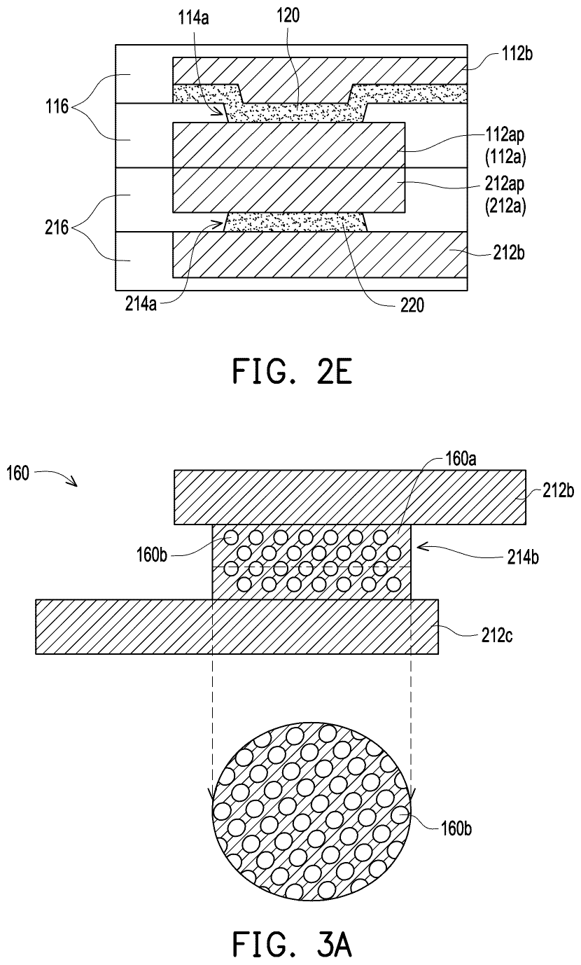

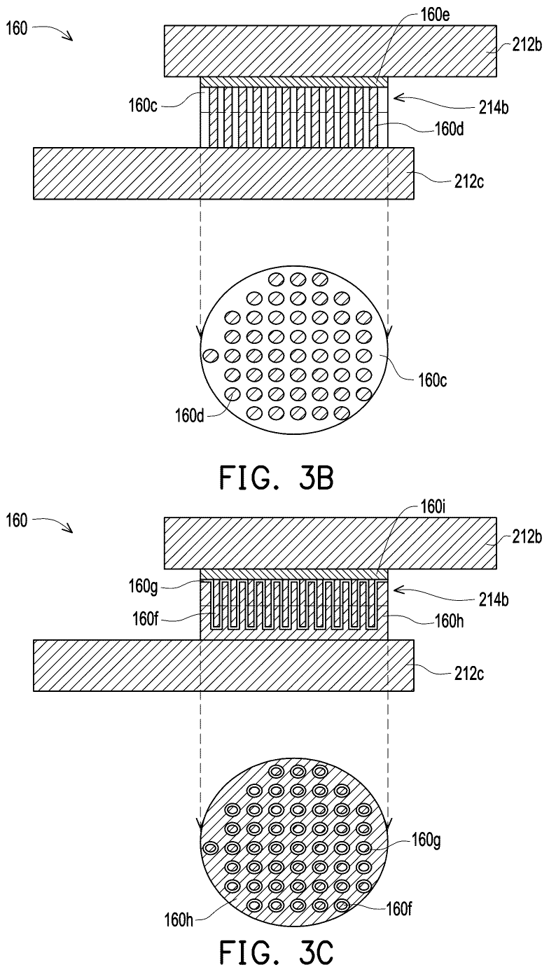

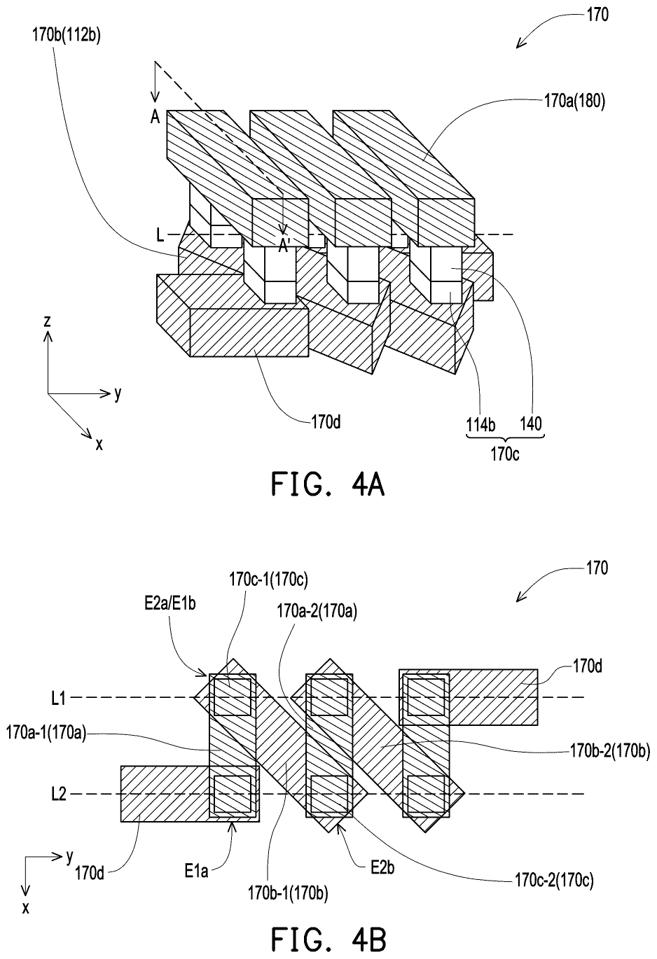

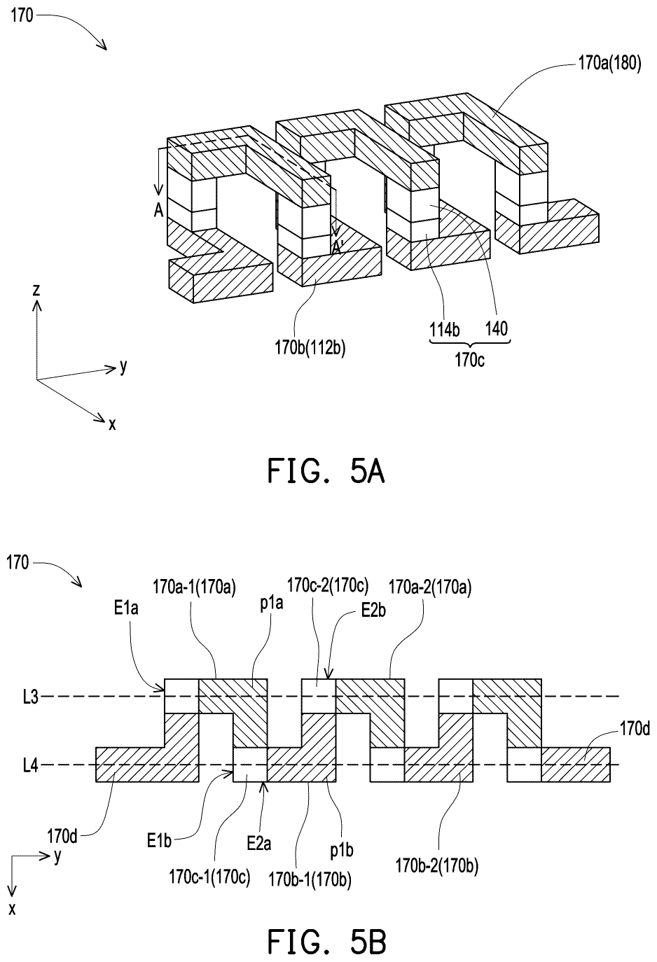

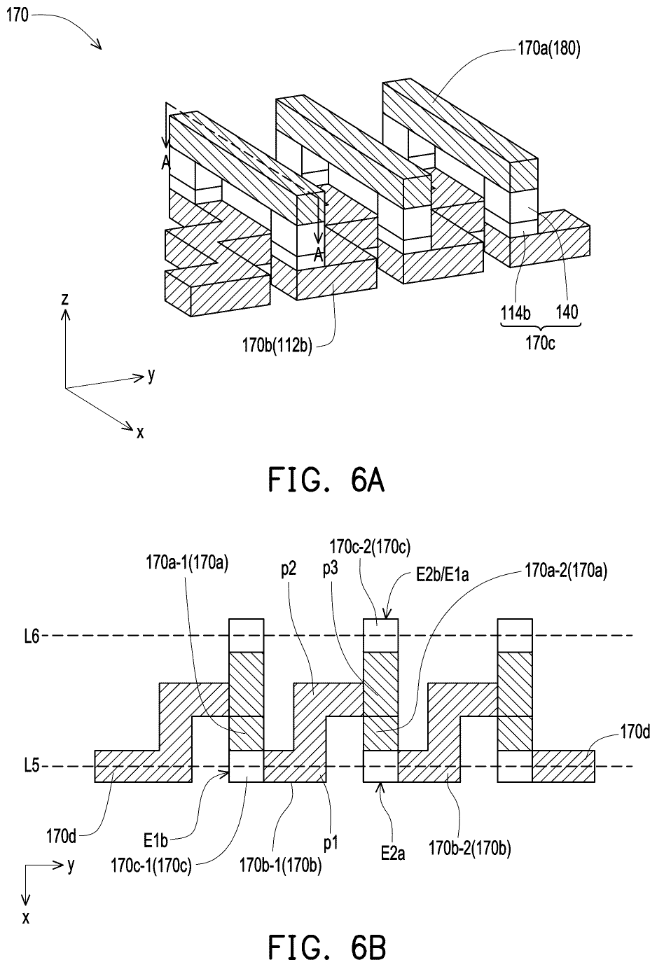

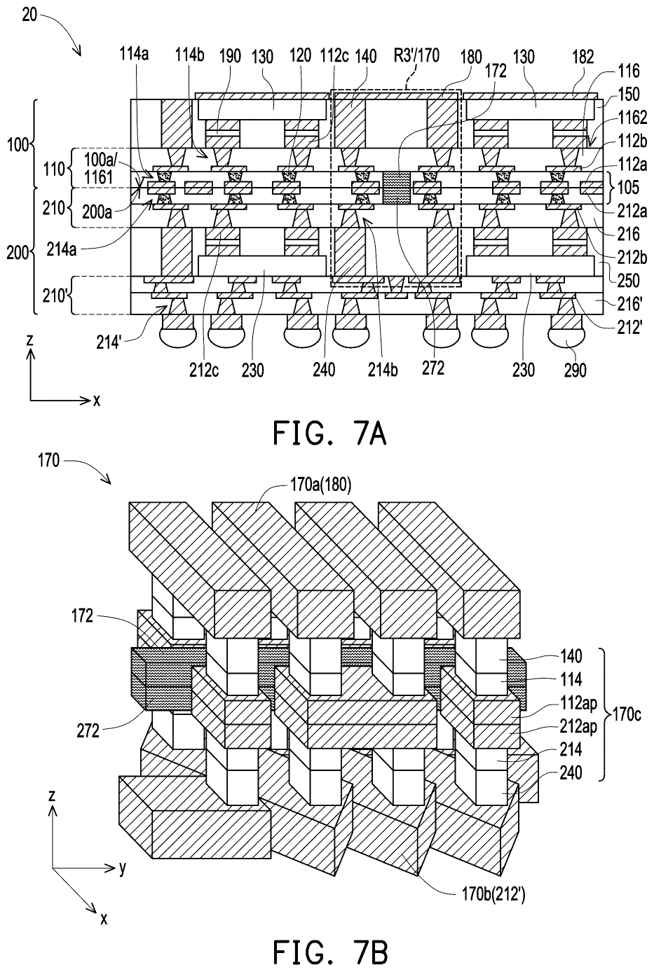

FIG. 1 is a schematic cross-sectional view of a stacked substrate structure according to an embodiment of the disclosure. FIG. 2A to FIG. 2E are partially enlarged schematic cross-sectional views of a stacked substrate structure according to an embodiment of the disclosure. FIG. 3A to FIG. 3C are partially enlarged schematic cross-sectional views of a stacked substrate structure according to an embodiment of the disclosure. FIG. 4A is a partial schematic three-dimensional view of a stacked substrate structure according to an embodiment of the disclosure. FIG. 4B is a schematic top view of FIG. 4A. FIG. 5A is a partial schematic three-dimensional view of a stacked substrate structure according to another embodiment of the disclosure. FIG. 5B is a schematic top view of FIG. 5A. FIG. 6A is a partial schematic three-dimensional view of a stacked substrate structure according to another embodiment of the disclosure. FIG. 6B is a schematic top view of FIG. 6A. FIG. 2A to FIG. 2E may be schematic cross-sectional views of various embodiments of a region R1 of FIG. 1. FIG. 3A to FIG. 3C may be schematic cross-sectional views of capacitors in various embodiments of a region R2 of FIG. 1. FIG. 4A, FIG. 5A, and FIG. 6A may be schematic three-dimensional views of inductors in various embodiments of region R3 in FIG. 1. For the sake of clarity, some components (e.g., a first insulation structure 116, a first molding body 150, a second insulation structure 216, a second molding body 250, etc.) are omitted in FIG. 4A to FIG. 4B, FIG. 5A to FIG. 5B, FIG. 6A to FIG. 6B, and FIG. 7B.

Referring to FIG. 1, a stacked substrate structure 10 includes a first structure 100 and a second structure 200. The first structure 100 is located above the second structure 200. The first structure 100 has a first bonding surface 100a, the second structure 200 has a second bonding surface 200a, and the first bonding surface 100a and the second bonding surface 200a are arranged face to face. The first structure and the second structure may also be stacked structures or other structures. The disclosure is directed to a stacked substrate structure and a manufacturing method thereof having a simplified manufacturing process and requiring less manufacturing costs.

The first structure 100 may include a first circuit structure 110. The first circuit structure 110 may include a first insulation structure 116, a plurality of first conductive layers 112, a plurality of first vias 114, and a first expansion modulation layer 120. The plurality of first conductive layers 112 may be disposed in or on the first insulation structure 116. The plurality of first vias 114 may be disposed in the first insulation structure 116 and between adjacent first conductive layers 112 to provide electrical connection of the adjacent first conductive layers 112 in a vertical direction z (also referred to as a z-direction). The first expansion modulation layer 120 may be disposed in part of the first vias 114 and/or between adjacent first conductive layers 112. Herein, the vertical direction z refers to a direction perpendicular to the first bonding surface 100a or the second bonding surface 200a. The first circuit structure and the second circuit structure may also be redistribution circuit structures or other structures.

For instance, the plurality of first conductive layers 112 may include a circuit layer 112a, a circuit layer 112b, and a circuit layer 112c. The circuit layer 112a, the circuit layer 112b, and the circuit layer 112c are stacked in the vertical direction z and are spaced apart from each other by the first insulation structure 116. The circuit layer 112a may be located on the first bonding surface 100a of the first structure 100, the circuit layer 112c is disposed on a first surface 1161 of the first insulation structure 116, and the circuit layer 112b is located between the circuit layer 112a and the circuit layer 112c. The circuit layer 112a may include a plurality of first bonding pads 112ap to serve as pads for external connection, so that the circuit layer 112a is also referred to as a first bonding pad layer 112a. The first bonding pad layer 112a and the circuit layer 112c are respectively located on two opposite sides of the first insulation structure 116. The first bonding surface 100a is essentially composed of a second surface 1162 of the first insulation structure 116 and a surface of the first bonding pad layer 112a. The plurality of first vias 114 may include vias 114a and vias 114b. The vias 114a are disposed between the first bonding pad layer 112a and the circuit layer 112b, and electrically connect the first bonding pad layer 112a and the circuit layer 112b. The vias 114b are disposed between the circuit layer 112b and the circuit layer 112c and electrically connect the circuit layer 112b and the circuit layer 112c. The first expansion modulation layer 120 may be disposed between the first bonding pad layer 112a and the circuit layer 112b, where a coefficient of thermal expansion of the first expansion modulation layer 120 is greater than that of the first conductive layer 112 (or the first bonding pad layer 112a), which helps to promote bonding of the first structure 100 and other components (such as the second structure described later).

In some embodiments, as shown in FIG. 2A, the first expansion modulation layer 120 may be located in the vias 114a. From another perspective, the vias 114a may be composed of the first expansion modulation layer 120. In some embodiments, the vias 114a may further include a seed layer (not shown), and the seed layer may be located between the first insulation structure 116 and the first expansion modulation layer 120.

In some embodiments, as shown in FIG. 2B, the first expansion modulation layer 120 may be located between the via 114a and the first bonding pad 112ap (or the first bonding pad layer 112a). For instance, the first expansion modulation layer 120 may extend along a side of the first bonding pad 112ap close to the via 114a.

In some embodiments, as shown in FIG. 2C, the first expansion modulation layer 120 may be located in the via 114a and extend toward the first bonding pad 112ap, for example, extend along one side of the first bonding pad 112ap close to the via 114a.

In some embodiments, as shown in FIG. 2D, the first expansion modulation layer 120 may be located in the via 114a and extend toward the first bonding pad 112ap and the circuit layer 112b. For instance, the first expansion modulation layer 120 may extend along a side of the first bonding pad 112ap close to the via 114a, and also extend along a side of the circuit layer 112b close to the via 114a.

In some embodiments, as shown in FIG. 2E, the first expansion modulation layer 120 may be located in the via 114a and extend toward the circuit layer 112b, for example, extend along a side of the circuit layer 112b close to the via 114a.

In some embodiments, the first expansion modulation layer 120 overlaps the first bonding pad 112ap in the vertical direction z.

It should be understood that FIG. 1 schematically illustrates three layers of the first conductive layers 112 and two layers of the first vias 114 in the first circuit structure 110, but the disclosure is not limited thereto, and the numbers and arrangements of the first conductive layers 112 and the first vias 114 may be adjusted according to actual needs. In addition, the first expansion modulation layer 120 is disposed between the first bonding pads 112ap and the circuit layer 112b in FIG. 1, but the disclosure is not limited thereto, and the position, quantity and size of the first expansion modulation layer 120 may be adjusted according to actual needs. In other embodiments, the first expansion modulation layer 120 may also be disposed in the vias 114b or between the circuit layer 112b and the circuit layer 112c.

In some embodiments, a material of the first conductive layer 112 and the first via 114 may include copper, titanium, gold, silver, tungsten, aluminum, alloys thereof, or other suitable conductive materials.

In some embodiments, a material of the first bonding pad 112ap (or the first bonding pad layer 112a) includes nanocrystalline copper (NC-Cu), nanotwinned copper (NT-Cu), nanocrystalline nanotwinned copper (NNT-Cu) or other suitable pad materials, which has rapid diffusion characteristics and is conducive to a bonding process. In some embodiments, a material of the wiring layers 112b and 112c may be the same as or different from that of the first bonding pad layer 112a, but the disclosure is not limited thereto.

In some embodiments, the first expansion modulation layer 120 may be a material with good electrical conductivity, thermal diffusivity, and a coefficient of thermal expansion greater than that of the first bonding pad 112ap. For instance, a material of the first expansion modulation layer 120 may include silver, aluminum, zinc, tin or other suitable materials. In other embodiments, the first expansion modulation layer 120 may include the same material as that of the first bonding pad 112ap, but have a different grain structure and a different coefficient of thermal expansion. For instance, a coefficient of thermal expansion of nanocrystalline nanotwinned copper (NNT-Cu) is greater than a coefficient of thermal expansion of nanotwinned copper (NT-Cu), and the coefficient of thermal expansion of nanotwinned copper (NT-Cu) is greater than a coefficient of thermal expansion of nanocrystalline copper (NC-Cu). Therefore, when the first bonding pad 112ap includes nanocrystalline nanotwinned copper (NNT-Cu) or nanotwinned copper (NT-Cu), the first expansion modulation layer 120 may include nanocrystalline copper (NC-Cu), and the coefficient of thermal expansion of the first expansion modulation layer 120 is greater than the coefficient of thermal expansion of the first bonding pad 112ap.

In some embodiments, the first insulation structure 116 may be formed by stacking a plurality of insulation layers. In some embodiments, a material of the first insulation structure 116 (or insulation layer) may be an insulation material with a low coefficient of thermal expansion, for example, an insulation material with a coefficient of thermal expansion between 0.01 ppm/K and 65 ppm/K. For instance, a material of the first insulation structure 116 may include polyimide (PI), polybenzoxazole (PBO), benzocyclobutene (BCB) or other suitable polymer materials. However, the disclosure is not limited thereto. In other embodiments, the material of the first insulation structure 116 may include silicon oxide or other suitable inorganic materials.

In some embodiments, the first structure 100 further includes a first chip 130 and a first molding body 150. The first chip 130 may be disposed on the first circuit structure 110 and electrically connected to the first circuit structure 110. For instance, the first chip 130 may be electrically connected to the circuit layer 112c through a conductive connector 190, where the conductive connector 190 includes, for example, a solder ball, solder paste, or other suitable conductive connection materials. In some embodiments, the first chip 130 may be a logic chip, a memory chip, an input/output chip, an integrated passive device (IPD) chip, an electrostatic discharge (ESD) protection device chip, or other suitable chips, which is not limited by the disclosure. In some embodiments, the first chip 130 may include an integrated circuit (EIC) chip, an optics integrated (PIC) chip, or a co-package of an integrated circuit (EIC) chip and an optics integrated (PIC) chip.

The first molding body 150 is disposed on the first circuit structure 110 and laterally encapsulates the first chip 130. In some embodiments, a top surface of the first molding body 150 is substantially aligned with a top surface of the first chip 130. In some embodiments, a material of the first molding body 150 may include epoxy, molding compound, or other similar materials.

In some embodiments, the first structure 100 further includes a first conductive pillar 140, which penetrates through the first molding body 150 and is electrically connected to the first circuit structure 110. In some embodiments, a top surface of the first conductive pillar 140 may be substantially aligned with the top surface of the first molding body 150. In some embodiments, a material of the first conductive pillar 140 may include copper, titanium, gold, silver, tungsten, aluminum, alloys thereof, or other suitable conductive materials. In some embodiments, the first conductive pillar 140 may be a cylinder, a square pillar, or other suitable shapes.

In some embodiments, the first conductive pillar 140 may be disposed around the first chip 130 to shield an electromagnetic wave signal and reduce the first chip 130 from being interfered by noise. In addition, the first conductive pillar 140 may also be used as a heat dissipation channel to improve heat dissipation efficiency of the first structure 100.

In some embodiments, the first structure 100 further includes a top conductive layer 180. The top conductive layer 180 may be disposed on the first molding body 150 and the first conductive pillar 140 to electrically connect with the first conductive pillar 140. In some embodiments, a material of the top conductive layer 180 may include copper, titanium, gold, silver, tungsten, aluminum, alloys thereof, or other suitable conductive materials.

In some embodiments, a heat sink 182 may be provided on a back side of the first chip 130 to improve heat dissipation efficiency of the first chip 130. In some embodiments, a material of the heat sink 182 may include copper, aluminum, alloys thereof, or other suitable heat dissipation materials.

In some embodiments, the second structure 200 may include a second circuit structure 210, a second chip 230, a second molding body 250, a second conductive pillar 240, and a third circuit structure 210′. The second chip 230, the second molding body 250 and the second conductive pillar 240 of the second structure 200 may be respectively similar to the first chip 130, the first molding body 150 and the first conductive pillar 140 of the first circuit structure 110, and for relevant description thereof, reference may be made to the above description, and detail thereof is not repeated.

In some embodiments, the second circuit structure 210 may include a second insulation structure 216, a plurality of second conductive layers 212 (for example, including a circuit layer 212a, a circuit layer 212b, and a circuit layer 212c), a plurality of second vias 214 (for example, including vias 214a and vias 214b), and a second expansion modulation layer 220 respectively similar to the first insulation structure 116, the plurality of first conductive layers 112 (for example, including the circuit layer 112a, the circuit layer 112b, and the circuit layer 112c), the plurality of first vias 114 (for example, including the vias 114a and the vias 114b), and the first expansion modulation layer 120 of the first circuit structure 110. For relevant description thereof, reference may be made to the above description, and details thereof are not repeated herein. In other embodiments, the second circuit structure 210 may not include the second expansion modulation layer 220.

In some embodiments, the circuit layer 212a is located on a second bonding surface 200a of the second structure 200. The circuit layer 212a includes a plurality of second bonding pads 212ap to serve as pads for external connection. Therefore, the circuit layer 212a is also referred to as second bonding pad layer 212a. The second bonding surface 200a is essentially composed of a surface of the second insulation structure 216 and a surface of the second bonding pad layer 212a.

The second bonding pad layer 212a may be connected with the first bonding pad layer 112a to form a bonding layer 105. For instance, the second bonding pads 212ap may be in direct contact with the corresponding first bonding pads 112ap to form a conductive bonding structure in the bonding layer 105, so that the first structure 100 and the second structure 200 are electrically connected. In some embodiments, the second insulation structure 216 of the second bonding surface 200a may be in direct contact with the first insulation structure 116 of the first bonding surface 200a, but the disclosure is not limited thereto. In other embodiments, the second insulation structure 216 of the second bonding surface 200a may be spaced apart from the first insulation structure 116 of the first bonding surface 200a without direct contact.

In some embodiments, the second expansion modulation layer 220 overlaps the second bonding pads 212ap in the vertical direction z. In FIG. 2A to FIG. 2E, the second expansion modulation layer 220 is schematically shown as being disposed in the vias 214a, but the disclosure is not limited thereto. The second expansion modulation layer 220 may be disposed in the same manner as the first expansion modulation layer 120 in the embodiments of FIG. 2A to FIG. 2E, or may be disposed between other adjacent circuit layers.

In some embodiments, a material of the second bonding pad 212ap (or the second bonding pad layer 212a) may be the same as the material of the first bonding pad 112ap (or the first bonding pad layer 112a). In some embodiments, a material of the second insulation structure 216 may be the same as the material of the first insulation structure 116.

In some embodiments, the third circuit structure 210′ of the second structure 200 may be disposed on one side of the second molding body 250 relative to the second circuit structure 210. Namely, the second molding body 250 is located between the third circuit structure 210′ and the second circuit structure 210. The third circuit structure 210′ may include a third insulation structure 216′, a plurality of third conductive layers 212′, and third vias 214′ connected between adjacent third conductive layers 212′. The second conductive pillar 240 and the second chip 230 may be electrically connected to the third conductive layers 212′ of the third circuit structure 210′.

In some embodiments, the second structure 200 further includes conductive terminals 290 disposed on the third conductive layer 212′ exposed by the third circuit structure 210′ to provide terminals for external connection of the stacked substrate structure 10. In some embodiments, the stacked substrate structure 10 may be electrically connected to a printed circuit board (not shown) or the like through the conductive terminals 290.

In some embodiments, the stacked substrate structure 10 further includes a capacitor 160. Capacitor 160 may be located in the first structure 100 and/or the second structure 200 and disposed close to the first chip 130 or the second chip 230. In some embodiments, the capacitor 160 may be disposed in part of the first vias 114 of the first circuit structure 110, in part of the second vias 214 of the second circuit structure 210, and/or in part of the third vias 214′ of the third circuit structure 210′. Specifically, part of the first vias 114, part of the second vias 214, and/or part of the third vias 214′ may have a metal-insulator-metal structure, so that the capacitor 160 is formed and is integrated in the first circuit structure 210, the second circuit structure 210, and/or the third circuit structure 210′. A space of the stacked substrate structure 10 is thus saved.

Taking one via 214b located between the circuit layer 212b and the circuit layer 212c in the second circuit structure 210 as an example, FIG. 3A to FIG. 3C show some embodiments of the capacitor 160. In some embodiments, as shown in FIG. 3A, the via 214b may include a porous metal material 160a and an insulation material 160b filled in pores of the porous metal material 160a. In this way, the porous metal material 160a and the insulation material 160b may construct metal-insulator-metal structures to form the capacitor 160. In some embodiments, the circuit layer 212b and the circuit layer 212c may act as an upper electrode and a lower electrode of the capacitor 160. In other words, the circuit layer 212b, the circuit layer 212c, and the via 214b sandwiched between the circuit layer 212b and the circuit layer 212c may constitute the capacitor 160.

In some embodiments, the porous metal material 160a may be a foamed metal, such as copper, nickel, aluminum, alloys thereof or other suitable foamed metals. The insulation material 160b may be a dielectric material with a high dielectric constant, such as Hafnium dioxide (HfO₂), zirconium dioxide (ZrO₂) or other suitable dielectric materials with high dielectric constants. In some embodiments, a pore diameter of the pores of the porous metal material 160a may be between 0.01 μm and 0.1 μm. In some embodiments, the porous metal material 160a may be formed by casting, sintering, gas injection, or other suitable methods. The insulation material 160b may be formed by chemical vapor deposition or other suitable methods.

In some embodiments, as shown in FIG. 3B, the via 214b may include a porous insulation material 160c and metal nanowires 160d filled with the porous insulation material 160c. In this way, the porous insulation material 160c and the metal nanowires 160d may form metal-insulator-metal structures to form the capacitor 160. In some embodiments, the circuit layer 212b and the circuit layer 212c may act as the upper electrode and the lower electrode of the capacitor 160. In other words, the circuit layer 212b, the circuit layer 212c, and the via 214b sandwiched between the circuit layer 212b and the circuit layer 212c may constitute the capacitor 160.

In some embodiments, the porous insulation material 160c may be an anodized aluminum material, and a material of the metal nanowire 160d may include copper, titanium, aluminum or other suitable metal materials. In the embodiment, formation of the capacitor 160 may include following steps. First, an aluminum substrate (not shown) may be formed on the circuit layer 212b, and then anodizing processing is performed on the aluminum substrate to form the porous insulation material 160c on the surface of the aluminum substrate. After that, metal nanowires 160d may be formed in the pores of the porous insulation material 160c through physical vapor deposition, electroplating or other suitable methods. In some embodiments, a portion of remaining aluminum substrate 160e that is not oxidized may remain between the porous insulation material 160c and the circuit layer 212b. In some embodiments, the metal nanowires 160d may be electrically connected between the remaining aluminum substrate 160e and the circuit layer 212c.

In some embodiments, as shown in FIG. 3C, the via 214b may include a porous metal material 160h, metal nanowires 160f filled in the pores of the porous metal material 160h, and an insulation material 160g located between the porous metal material 160h and the metal nanowires 160f. In this way, the porous metal material 160h, the insulation material 160g and the metal nanowires 160f may form metal-insulator-metal structures to form the capacitor 160. In some embodiments, the circuit layer 212b and the circuit layer 212c may act as the upper electrode and the lower electrode of the capacitor 160. In other words, the circuit layer 212b, the circuit layer 212c, and the via 214b sandwiched between the circuit layer 212b and the circuit layer 212c may constitute the capacitor 160.

In some embodiments, the insulation material 160g may be a high-k dielectric material, such as hafnium dioxide (HfO₂), zirconium dioxide (ZrO₂) or other suitable high-k dielectric material, and the materials of the porous metal material 160h and the metal nanowire 160f may respectively include copper, titanium, aluminum or other suitable metal materials. In the embodiment, formation of the capacitor 160 may include the following steps. First, an aluminum substrate (not shown) may be formed on the circuit layer 212b, and then the aluminum substrate is subjected to anodizing processing to form an anodized aluminum material with pores (not shown) on the surface of the aluminum substrate. Then, metal nanowires 160f may be formed in the pores of the anodized aluminum material through physical vapor deposition, electroplating or other suitable methods. In some embodiments, a portion of remaining aluminum substrate 160i that is not oxidized may remain between the metal nanowires 160f and the circuit layer 212b. Next, the anodized aluminum material may be removed through a wet etching process or other suitable methods. Then, the insulation material 160g may be conformally formed on the surface of the metal nanowire 160f through chemical vapor deposition, atomic layer deposition, or other suitable methods. Thereafter, the porous metal material 160h may be formed on the insulation material 160g through physical vapor deposition, electroplating or other suitable methods.

In some embodiments, the stacked substrate structure 10 further includes an inductor 170. The inductor 170 may be located in the first structure 100 and/or the second structure 200. For instance, the inductor 170 may be separately provided in the first structure 100 (as shown in FIG. 1) or the second structure 200, or may be disposed by stretching over the first structure 100 or the second structure 200 (as shown in FIG. 7A). In some embodiments, taking the inductor 170 located in the first structure 100 as an example, as shown in FIG. 1, the inductor 170 may be disposed in the first molding body 150 and the first circuit structure 110 and may be formed by a portion of the top conductive layer 180, the first conductive pillar 140, a portion of the first conductive layer 112, and a portion of the first vias 114. In this way, the inductor 170 may be integrated into the first molding body 150 and the first circuit structure 110, and the space in the stacked substrate structure 10 is thereby saved.

FIG. 4A to FIG. 4B, FIG. 5A to FIG. 5B, and FIG. 6A to FIG. 6B illustrate some embodiments of the inductor 170, and a region R3 of FIG. 1 may be a cross-section cut along a section line A-A′ of FIG. 4A, FIG. 5A, or FIG. 6A. For convenience of explanation, a dotted line L is shown in FIG. 4A, dotted lines L1 and L2 are shown in FIG. 4B, dotted lines L3 and L4 are shown in FIG. 5B, and dotted lines L5 and L6 are shown in FIG. 6B. However, it should be understood that the dotted lines L and L1, L2, L3, L4, L5, L6 actually do not exist in the structure.

In some embodiments, as shown in FIG. 4A, the inductor 170 may include a top circuit layer 170a, a bottom circuit layer 170b, and a plurality of vertical connectors 170c located between the top circuit layer 170a and the bottom circuit layer 170b. The top circuit layer 170a may be formed by, for example, a portion of the top conductive layer 180. The bottom circuit layer 170b may be formed by, for example, a portion of the first conductive layer 112 (e.g., the circuit layer 112b) of the first circuit structure 110. The vertical connectors 170c may be formed by, for example, the first conductive pillar 140 and the first vias (e.g., vias 114b).

In some embodiments, referring to FIG. 4A and FIG. 4B, the top circuit layer 170a may include a plurality of top circuit segments arranged in a y-direction and parallel to each other (for example, including top circuit segments 170a-1, 170a-2, etc.). The bottom circuit layer 170b may include a plurality of bottom circuit segments arranged in the y-direction (for example, including bottom circuit segments 170b-1, 170b-2, etc.). An extending direction (e.g., an x-direction) of the top circuit segments (e.g., 170a-1 and 170a-2) is different from an extending direction of the bottom circuit segments (e.g., 170b-1 and 170b-2). Therefore, from a top viewing angle, the top circuit segments intersect the bottom circuit segments. In some embodiments, the x-direction, y-direction, and a z-direction are perpendicular to each other. The plurality of vertical connectors 170c (e.g., vertical connectors 170c-1 and 170c-2) may be respectively disposed between one end of the top circuit segment and one end of the corresponding bottom circuit segment. For instance, the vertical connector 170c-1 is disposed between a second end E2a of the top circuit segment 170a-1 and a first end E1b of the bottom circuit segment 170b-1 to electrically connect the top circuit segment 170a-1 with the bottom circuit segment 170b-1.

In some embodiments, the top circuit segments (e.g., top circuit segments 170a-1 and 170a-2) and the bottom circuit segments (e.g., bottom circuit segments 170b-1 and 170b-2) are linear. In some embodiments, the first ends E1b of the plurality of bottom circuit segments (e.g., bottom circuit segments 170b-1 and 170b-2) and the second ends E2a of the plurality of top circuit segments (such as top circuit segments 170a-1 and 170a-2) are arranged on the dotted line L1. Second ends E2b of the plurality of bottom circuit segments (e.g., bottom circuit segments 170b-1 and 170b-2) and first ends E1a of the plurality of top circuit segments (e.g., top circuit segments 170a-1 and 170a-2) are arranged on the dotted line L2. The dotted line L1 and the dotted line L2 are parallel to each other and extend in the y-direction. In addition, the second end E2b of the bottom circuit segment (e.g., bottom circuit segment 170b-1) may be arranged in the x-direction with the first end E1b of the bottom circuit segment (e.g., bottom circuit segment 170b-2). In detail, the first end E1a of the top circuit segment (e.g., top circuit segment 170a-1) is on the dotted line L2 and extends in a −x-direction to the second end E1a of the top circuit segment (e.g., the top circuit segment 170a-1) on the dotted line L1. The first end E1b of the bottom circuit segment (e.g., bottom circuit segment 170b-1) is on the dotted line L1 and extends in a diagonal direction to the second end E2b of the bottom circuit segment (e.g., the bottom circuit segment 170b-1) on the dotted line L2. The diagonal direction is a direction that forms a positive angle with the x-direction, and the positive angle is greater than 0 degree and less than 90 degrees. The vertical connector 170c may be located between the first end E1a of the top circuit segment (e.g., top circuit segment 170a-2) and the second end E2b of the bottom circuit segment (e.g., bottom circuit segment 170b-1) or between the second end E2a of the top circuit segment (e.g., top circuit segment 170a-2) and the first end E1b of the bottom circuit segment (e.g., bottom circuit segment 170b-2). However, the disclosure is not limited thereto. The shapes of the top circuit segments and the bottom circuit segments may be the same or different and may be adjusted according to actual needs.

In other embodiments, as shown in FIGS. 5A and 5B, shapes of the top circuit segments (e.g., top circuit segments 170a-1 and 170a-2) and bottom circuit segments (e.g., bottom circuit segments 170b-1 and 170b-2) are L-shaped. From a top viewing angle, L-shaped turning points p1a of the top circuit segments (e.g., top circuit segments 170a-1 and 170a-2) are arranged on a dotted line L3, while L-shaped turning points p1b of the bottom circuit segments (e.g., bottom circuit segments 170b-1 and 170b-2) are arranged on another dotted line L4. The dotted line L3 and the dotted line L4 are parallel to each other and extend in the y-direction. In detail, the L-shaped first end E1a of the top circuit segment (e.g., the top circuit segment 170a-1) is on the dotted line L3 and extends in the y-direction to the turning point p1a and then turns to extend in the x-direction to the second end E2a on the dotted line L4. The L-shaped first end E1b of the bottom circuit segment (e.g., the bottom circuit segment 170b-1) is on the dotted line L4 and extends in the y-direction to the turning point p1b and then turns to extend in the −x-direction to the second end E2b on the dotted line L3. Namely, the L-shaped turning point p1a of the top circuit segment (e.g., top circuit segment 170a-2) is between the second ends E2b of the adjacent bottom circuit segments (e.g., bottom circuit segments 170b-1 and 170b-2), and the L-shaped turning point p1b of the bottom circuit segment (e.g., bottom circuit segment 170b-1) is between the second ends E2a of the adjacent top circuit segments (e.g., top circuit segments 170a-1 and 170a-2). The vertical connector 170c may be located between the first end E1a of the top circuit segment (e.g., top circuit segment 170a-2) and the second end E2b of the bottom circuit segment (e.g., bottom circuit segment 170b-1) or between the second end E2a of the top circuit segment (e.g., top circuit segment 170a-2) and the first end E1b of the bottom circuit segment (e.g., bottom circuit segment 170b-2).

In some other embodiments, as shown in FIG. 6A and FIG. 6B, a shape of the top circuit segments (e.g., top circuit segments 170a-1 and 170a-2) may be linear, while a shape of the bottom circuit segments (e.g., bottom circuit segments 170b-1 and 170b-2) may be a stepped shape. The stepped shape may be composed of a plurality of L shapes connected in series (e.g., a tail end of an L shape is connected to a head end of a subsequent L shape). In FIG. 6B, the shape of the bottom circuit segments (e.g., the bottom circuit segments 170b-1 and 170b-2) is a two-step stairs shape with three turning points. In some embodiments, the first ends E1b of the plurality of bottom circuit segments (e.g., bottom circuit segments 170b-1 and 170b-2) are arranged on a dotted line L5, and the second ends E2b of the plurality of bottom circuit segments (e.g., bottom circuit segments 170b-1 and 170b-2) are arranged on a dotted line L6. The dotted line L5 and the dotted line L6 are parallel to each other and extend in the y-direction. Furthermore, the second end E2b of the bottom circuit segment (e.g., bottom circuit segment 170b-1) may be aligned with the first end E1b of another bottom circuit segment (e.g., bottom circuit segment 170b-2) in the x-direction. In detail, the first end E1b of the bottom circuit segment (e.g., bottom circuit segment 170b-1) is on the dotted line L5 and extends in the y-direction to a first turning point p1, turns to extend in the −x-direction to a second turning point p2, extends from the second turning point p2 in the y-direction to a third turning point p3, and then turns to extend in the −x-direction to the second end E2b located on the dotted line L6.

In FIG. 6B, the first ends E1a of the top circuit segment (e.g., the top circuit segments 170a-1 and 170a-2) extend in the x-direction to the second end E2b. From a top viewing angle, a portion of the bottom circuit segment (for example, the part from the third turning point p3 to the second end E2b of the bottom circuit segment 170b-1) may overlap with the top circuit segment (e.g., the top circuit segment 170a-2).

In some embodiments, the two ends of the bottom circuit segment (e.g., bottom circuit segment 170b-1) may respectively correspond to the ends of different top circuit segments (such as 170a-1 and 170a-2). Through the connection of different vertical connectors 170c, a coil structure surrounding the dotted line L (indicated in FIG. 4A) counterclockwise or clockwise is formed. For instance, as shown in FIG. 4A and FIG. 4B, FIG. 5A and FIG. 5B, or FIG. 6A and FIG. 6B, the top circuit segment 170a-1 may be connected to the bottom circuit segment 170b-1 through the vertical connector 170c-1, and the bottom circuit segment 170b-1 may be connected to another top circuit segment 170a-2 through another vertical connector 170c-2, so as to form a coil surrounding the dotted line L. Deduced by analogy, the plurality of top circuit segments, the plurality of vertical connectors 170c and the plurality of bottom circuit segments may form a plurality of coils connected to each other, so as to form the inductor 170. The inductor 170 may be, for example, an air core inductor.

In some embodiments, both ends of the inductor 170 may be electrically connected to a corresponding circuit layer through a connection circuit segment 170d. For instance, the connection circuit segment 170d may be formed by part of the first conductive layers 112 (e.g., the circuit layer 112b) and may be physically and electrically connected to the bottom circuit layer 170b or the vertical connector 170c of the inductor 170. However, the disclosure is not limited thereto, and the configuration of the connection circuit segment 170d and the inductor 170d may be adjusted according to actual needs. In other embodiments, the connection circuit segment 170d may be formed from a portion of the top conductive layer 180 and may be physically and electrically connected to the top circuit layer 170a or the vertical connector 170c of the inductor 170.

In FIG. 4A, FIG. 5A and FIG. 6A, a portion of the circuit layer 112b is schematically shown as the bottom circuit layer 170b of the inductor 170, but this is not intended to limit the disclosure. The bottom circuit layer 170b of the inductor 170 may be formed by any layer of the first conductive layers 112. The vertical connector 170c of the inductor 170 is formed by the first via 114 and the first conductive pillar 140 located between the bottom circuit layer 170b and the top circuit layer 170a and stacked in the z-direction.

In addition, in other embodiments, the inductor 170 may be integrated into a semiconductor substrate of the first chip 130 or the second chip 230, and have a similar structure to the inductor shown in FIG. 4A, FIG. 5A, and FIG. 6A, but the vertical connector 170c of the inductor 170 is composed of a through-hole penetrating through the semiconductor substrate, and the top circuit layer 170a and the bottom circuit layer 170b are composed of conductive layers formed on both sides of the semiconductor substrate.

In some embodiments, the first structure 100 may further include a waveguide duct 142, a waveguide layer 145 and an integrated optical path chip 132. The waveguide duct 142 may be located in the first molding body 150. The waveguide layer 145 may be disposed in the first insulation structure 116 and optically connected to the waveguide duct 142. The integrated optical path chip 132 may be disposed on the first molding body 150 and optically connected to the corresponding waveguide duct 142. In this way, a light transmission path is provided in the stacked substrate structure 10, and a speed of long-distance signal transmission increases. In some embodiments, a material of the waveguide duct 142 and the waveguide layer 145 may include glass, polymer materials, semiconductor materials or other suitable materials, which is not limited by the disclosure as long as the materials are suitable for transmitting light of a set wavelength range.

In some embodiments, the integrated optical path chip 132 may be connected to an optical fiber 135, and a portion of the first chip 130 may be a co-package of an integrated circuit (EIC) chip and an integrated optical circuit (PIC) chip, so that the first chip 130 may be optically connected to the waveguide layer 145. In this way, optical signals may be transmitted from the optical fiber 135 to the first chip 130 through the integrated optical path chip 132, the waveguide duct 142, and the waveguide layer 145, and vice versa.

In FIG. 1, the waveguide duct 142, the waveguide layer 145 and the integrated optical path chip 132 are disposed in the first structure 100, but this is not intended to limit the disclosure. The waveguide duct 142, the waveguide layer 145 and the integrated optical path chip 132 may also be disposed in the second structure 200.

FIG. 7A is a schematic cross-sectional view of a stacked substrate structure according to an embodiment of the disclosure. FIG. 7B is a partial schematic three-dimensional view of the stacked substrate structure according to an embodiment of the disclosure. It must be noted herein that the embodiment of FIG. 7A and FIG. 7B uses the component referential numbers and part of the content of the embodiment of FIG. 1 and FIG. 4A, where the same or similar referential numbers are used to represent the same or similar components, and description of the same technical content is omitted. For the description of the omitted parts, reference may be made to the foregoing embodiments and details thereof are not repeated herein.

Referring to FIG. 7A and FIG. 7B, a difference between a stacked substrate structure 20 and the embodiment of FIG. 1 is that the inductor 170 of the stacked substrate structure 20 is disposed by stretching across the first structure 100 and the second structure 200. To be specific, the inductor 170 may be disposed in the first molding body 150, the first circuit structure 110, the second circuit structure 210, the second molding body 250 and the third circuit structure 210′, and may be formed by a portion of the top conductive layer 180, the first conductive pillar 140, a portion of the first conductive layer 112, a portion of the first vias 114, a portion of the second conductive layer 212, a portion of the second vias 214, the second conductive pillar 240, and a portion of the third conductive layer 212′. For instance, the top circuit layer 170a of the inductor 170 may be, for example, formed by a portion of the top conductive layer 180. The bottom circuit layer 170b may be, for example, formed by a portion of the third conductive layer 212′ of the third circuit structure 210′. The vertical connector 170c may be, for example, formed by the first conductive pillar 140, the first via 114, the first bonding pad 112ap, the second bonding pad 212ap, the second via 214, and the second conductive pillar 240 stacked in the vertical direction z. In some embodiments, since the first expansion modulation layer 120 and the second expansion modulation layer 220 may be disposed in part of the first vias 114 and part of the second vias 214 respectively, the vertical connector 170c may include the first expansion modulation layer 120 and/or the second expansion modulation layer 220.

In some embodiments, the inductor 170 may further include a first magnetic material 172 and a second magnetic material 272. The first magnetic material 172 may be disposed in the first insulation structure 116 of the first structure 100 and located at the first bonding surface 100a. The second magnetic material 272 may be disposed in the second insulation structure 216 of the second structure 200 and located at the second bonding surface 200a. In this way, the first magnetic material 172 and the second magnetic material 272 may be bonded to each other in the bonding layer 105 to become a single part. A coil structure of the inductor 170 may surround the first magnetic material 172 and the second magnetic material 272, so that the inductor 170 becomes a magnetic core inductor. However, the disclosure is not limited thereto. The inductor 170 may be an air-core inductor without including the first magnetic material 172 and the second magnetic material 272. In addition, the top circuit layer and the bottom circuit layer of the inductor 170 may be configured with reference to FIG. 4A to FIG. 4B, FIG. 5A to FIG. 5B, FIG. 6A to FIG. 6B, or other embodiments, but the disclosure is not limited thereto.

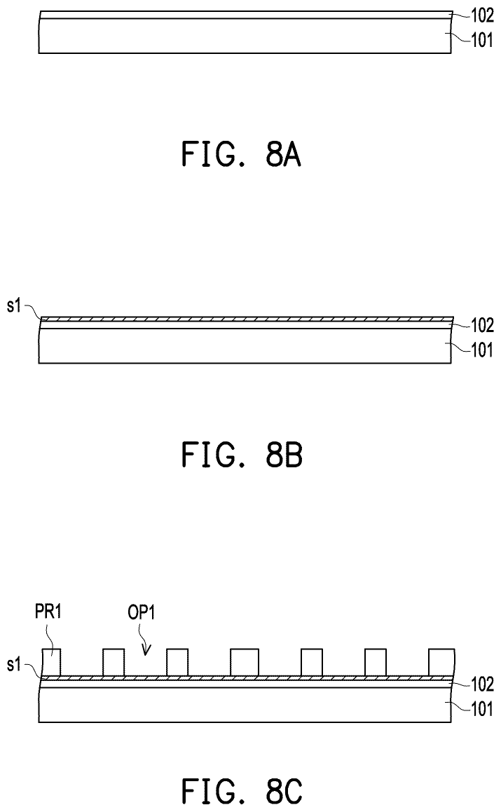

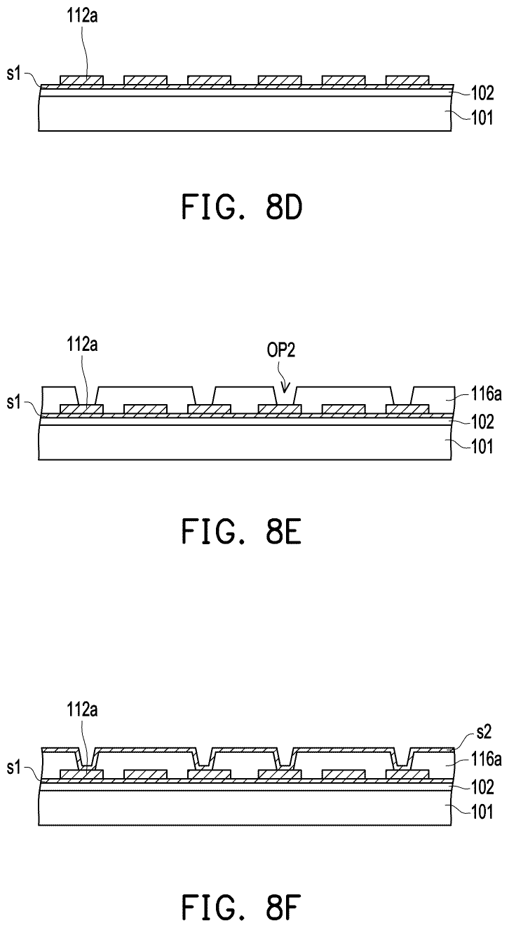

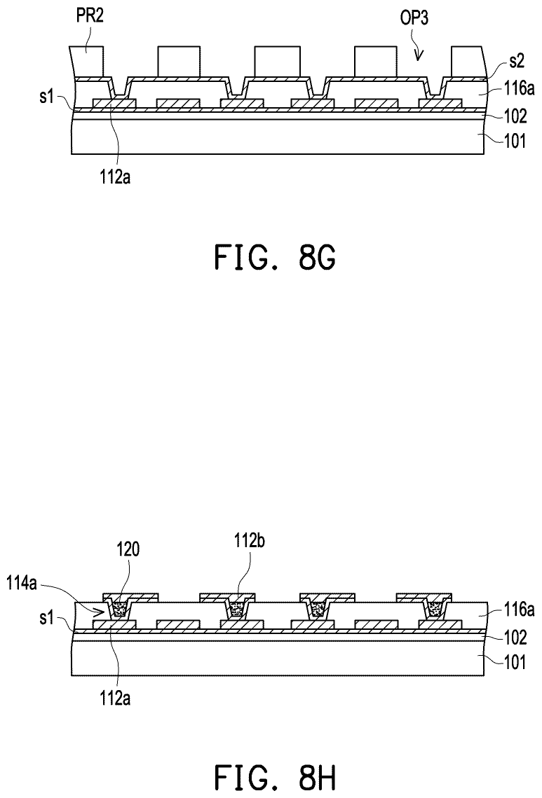

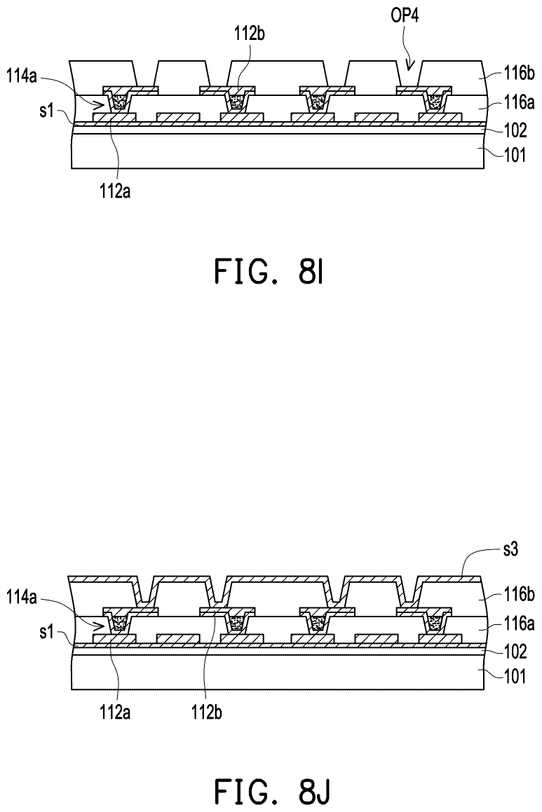

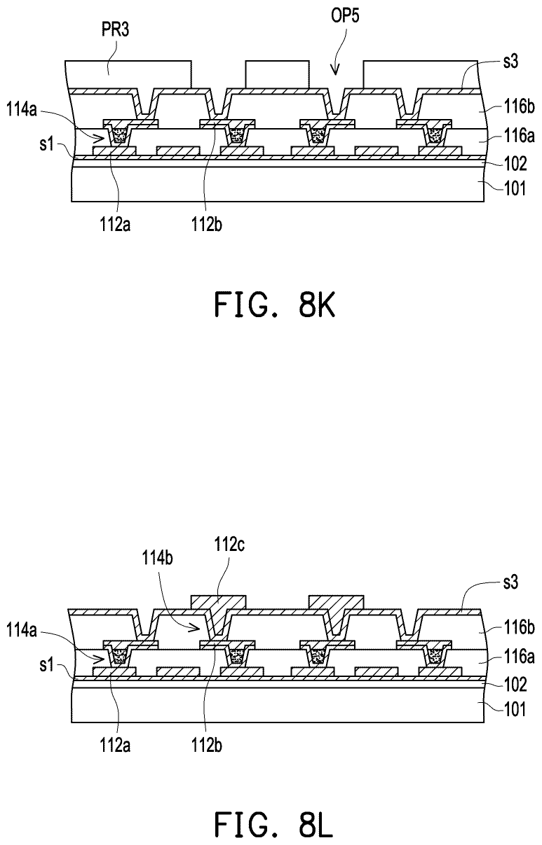

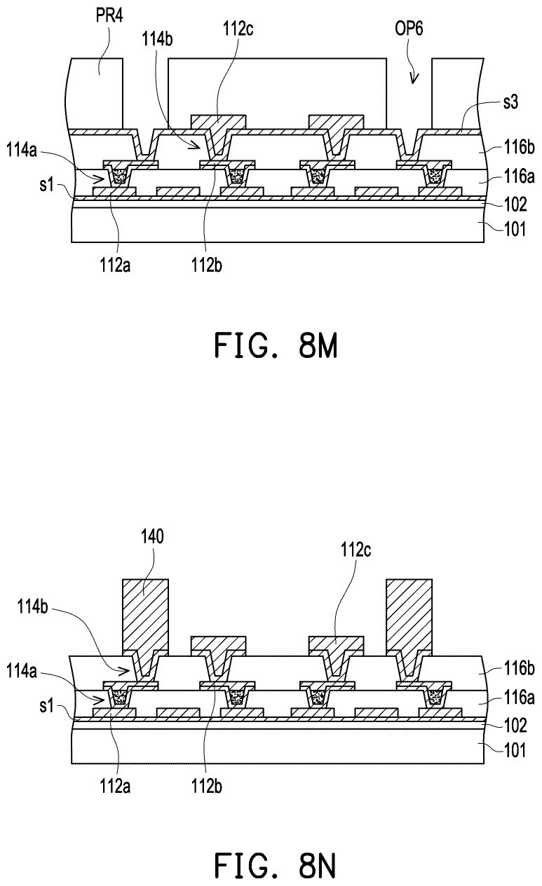

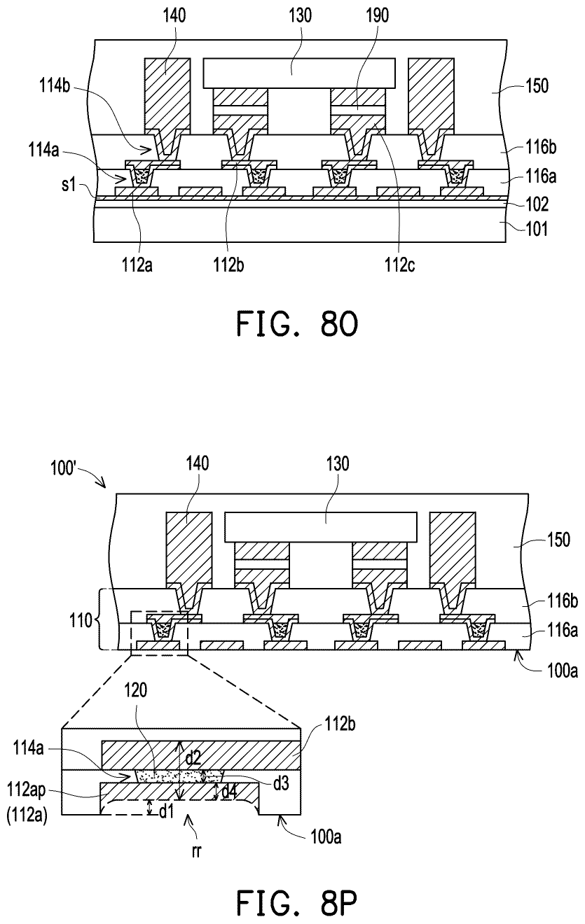

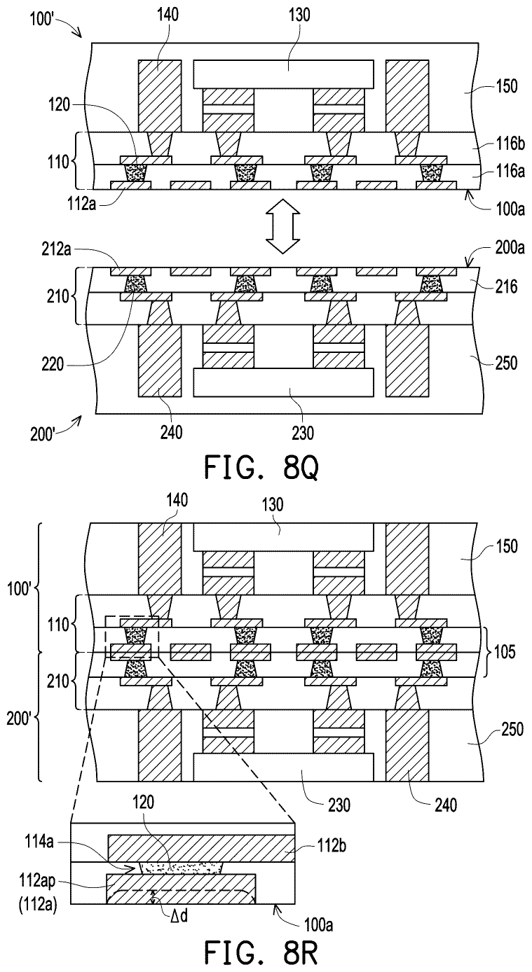

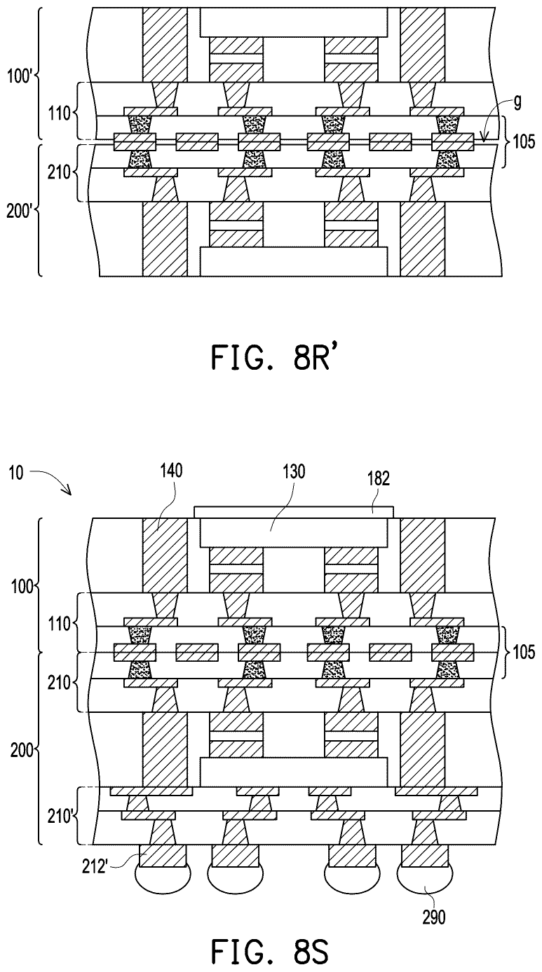

FIG. 8A, FIG. 8B, FIG. 8C, FIG. 8D, FIG. 8E, FIG. 8F, FIG. 8G, FIG. 8H, FIG. 8I, FIG. 8J, FIG. 8K, FIG. 8L, FIG. 8M, FIG. 8N, FIG. 8O, FIG. 8P, FIG. 8Q, FIG. 8R, FIG. 8R′, and FIG. 8S are schematic cross-sectional views of a manufacturing process of a stacked substrate structure according to an embodiment of the disclosure. It must be noted here that the embodiments of FIG. 8A, FIG. 8B, FIG. 8C, FIG. 8D, FIG. 8E, FIG. 8F, FIG. 8G, FIG. 8H, FIG. 8I, FIG. 8J, FIG. 8K, FIG. 8L, FIG. 8M, FIG. 8N, FIG. 8O, FIG. 8P, FIG. 8Q, FIG. 8R, FIG. 8R′, and FIG. 8S adopt the component referential numbers and part of the content of the embodiment of FIG. 1, where the same or similar referential numbers are used to represent the same or similar components, and explanations of the same technical content are omitted. For description of omitted parts, reference may be made to the foregoing embodiments and details thereof are not repeated herein. For convenience of illustration, the seed layers (such as seed layers s2 and s3) are omitted from the partial enlarged view of FIG. 8P, FIG. 8Q, FIG. 8R, FIG. 8R′, and FIG. 8S.

Referring to FIG. 8A, a release layer 102 is formed on a carrier board 101. The carrier board 101 may be a glass substrate, a silicon wafer, a ceramic substrate, or other suitable carrier boards to serve as a support for structures subsequently formed thereon. The release layer 102 may be made of a material whose adhesion force may be reduced through a thermal process, an ultraviolet (UV) process, a laser process or other similar processes, so that the carrier board 101 and the structures formed thereon may be easily separated in subsequent processes. For instance, the release layer 102 may be a photothermal conversion coating, polyimide or other suitable materials.

Referring to FIG. 8B, a seed layer s1 is formed on the release layer 102. The seed layer s1 may be formed through sputtering or other suitable processes. In some embodiments, the seed layer s1 may include titanium, copper, combinations thereof, or other suitable materials.

Referring to FIG. 8C, a photoresist layer PR1 is formed on the seed layer s1, where the photoresist layer PR1 has a plurality of openings OP1 to expose a portion of the seed layer s1. For instance, a photoresist material layer (not shown) may be formed on the seed layer s1 by spin coating or other suitable methods, and then the photoresist material layer may be subjected to an exposure and development process through a photomask (not shown) to form the photoresist layer PR1.

Referring to FIG. 8D, a first bonding pad layer 112a is formed in the plurality of openings OP1. For instance, the first bonding pad layer 112a may be formed in the plurality of openings OP1 through electroplating or other suitable methods. In some embodiments, after the first bonding pad layer 112a is formed, the first expansion modulation layer 120 may be formed on the first bonding pad layer 112a and in the plurality of openings OP1 through electroplating or other suitable methods. Then, the photoresist layer PR1 is removed.

Referring to FIG. 8E, a first insulation layer 116a is formed on the seed layer s1 and the first bonding pad layer 112a. For instance, an insulation material layer (not shown) may be formed on the seed layer s1 and the first bonding pad layer 112a through chemical vapor deposition, physical vapor deposition, or other suitable deposition methods. Next, through a photolithography and etching process, a plurality of openings OP2 are formed in the insulation material layer to form the first insulation layer 116a. The plurality of openings OP2 may expose a portion of the first bonding pad layer 112a.

Referring to FIG. 8F, a seed layer s2 is formed on the first insulation layer 116a and on sidewalls and bottom surfaces of the openings OP2. The seed layer s2 may be formed through sputtering or other suitable processes. In some embodiments, the seed layer s2 may be made of titanium, copper, combinations thereof, or other suitable materials.

Referring to FIG. 8G, a photoresist layer PR2 is formed on the seed layer s2. The photoresist layer PR2 has a plurality of openings OP3 to expose portions of the seed layer s2 and the openings OP2. For instance, a photoresist material layer (not shown) may be formed on the seed layer s2 by spin coating or other suitable methods, and then the photoresist material layer is subjected to an exposure and development process through a photomask (not shown) to form the photoresist layer PR2.

Referring to FIG. 8H, vias 114a are formed in the openings OP2, and a circuit layer 112b is formed in the openings OP3. For instance, the first expansion modulation layer 120 may be formed on the seed layer s2 in the openings OP2 through electroplating or other suitable methods, so that the first expansion modulation layer 120 and the seed layer s2 thereunder construct the vias 114a. Next, a conductive material layer is formed on the first expansion modulation layer 120 and the seed layer s2 in the openings OP3 through electroplating or other suitable methods, so that the conductive material layer and the seed layer s2 thereunder construct the circuit layer 112b. In some embodiments, the first expansion modulation layer 120 may also be formed in part of the openings OP3 and located on the first insulation layer 116a. Thereafter, the photoresist layer PR2 and the seed layer s2 not covered by the circuit layer 112b are removed.

Referring to FIG. 8I, a second insulation layer 116b is formed on the circuit layer 112b and the first insulation layer 116a. For instance, an insulation material layer (not shown) may be formed on the circuit layer 112b and the first insulation layer 116a through chemical vapor deposition, physical vapor deposition, or other suitable deposition methods. Next, a plurality of openings OP4 are formed in the insulation material layer through a photolithography and an etching process to form the second insulation layer 116b. The plurality of openings OP4 may expose a portion of the circuit layer 112b. The first insulation layer 116a and the second insulation layer 116b may form the first insulation structure 116.

Referring to FIG. 8J, a seed layer s3 is formed on the second insulation layer 116b and on sidewalls and bottom surfaces of the openings OP4. The seed layer s3 may be formed through sputtering or other suitable processes. In some embodiments, the seed layer s3 may include titanium, copper, combinations thereof, or other suitable materials.

Referring to FIG. 8K, a photoresist layer PR3 is formed on the seed layer s3. The photoresist layer PR3 has a plurality of openings OP5 to expose a portion of the seed layer s3 and the openings OP4. For instance, a photoresist material layer (not shown) may be formed on the seed layer s3 by spin coating or other suitable methods, and then the photoresist material layer may be subjected to an exposure and development process through a photomask (not shown) to form the photoresist layer PR3.

Referring to FIG. 8L, vias 114b are formed in the openings OP4, and a circuit layer 112c is formed in the openings OP5. For instance, a conductive material layer may be formed in the openings OP4 and the openings OP5 through electroplating or other suitable methods, where the conductive material layer located in the openings OP4 and the underlying seed layer s3 constitute the vias 114b, and the conductive material layer located in the openings OP5 and the underlying seed layer s3 constitute the circuit layer 112c. The photoresist layer PR3 is then removed.

In some embodiments, the capacitor 160 as shown in FIG. 3A, FIG. 3B, or FIG. 3C may be formed in part of the openings OP4.

Referring to FIG. 8M, a photoresist layer PR4 is formed on the seed layer s3. The photoresist layer PR4 has a plurality of openings OP6 to expose a portion of the seed layer s3 and the openings OP4. The opening OP4 and the opening OP6 substantially overlap in the vertical direction z. For instance, a photoresist material layer (not shown) may be formed on the seed layer s3 by spin coating or other suitable methods, and then the photoresist material layer may be subjected to an exposure and development process through a photomask (not shown) to form the photoresist layer PR4.

Referring to FIG. 8N, the vias 114b is formed in the openings OP4, and first conductive pillars 140 are formed in the openings OP6. For instance, a conductive material layer may be formed in the openings OP4 and the openings OP6 through electroplating or other suitable methods. The conductive material layer located in the openings OP4 and the underlying seed layer s3 constitute the vias 114b, and the conductive material layer located in the openings OP6 constitutes the first conductive pillars 140. The first conductive pillars 140 are physically and electrically connected to the vias 114b thereunder. The photoresist layer PR4 is then removed.

Referring to FIG. 8O, the first chip 130 is bonded to the circuit layer 112c. For instance, the first chip 130 may be bonded to the circuit layer 112c through the conductive connector 190. Next, a first molding body 150 is formed on the second insulation layer 116b, where the first molding body 150 may encapsulate the first chip 130 and the first conductive pillars 140.

Referring to FIG. 8P, the carrier board 101 is peeled off by using the release layer 102, and then the seed layer s1 is removed to expose the first insulation layer 116a and the first bonding pad layer 112a. For instance, the release layer 102 may be subjected to a thermal process, an ultraviolet (UV) process, a laser process or other suitable processes to remove the carrier board 101 and the release layer 102. In some embodiments, a descum process may be performed to remove the release layer 102 that may remain on the seed layer s1. Next, the seed layer s1 may be removed through a wet etching process to expose the surfaces of the first insulation layer 116a and the first bonding pad layer 112a.

In some embodiments, during the process of removing the seed layer s1, the first bonding pad layer 112a (or the first bonding pad 112ap) may also be etched to form a recess rr, which may affect a yield of subsequent bonding. Therefore, a distance Δd (shown in FIG. 8R) of displacement of the surface of the first bonding pad layer 12a in the vertical direction z due to thermal expansion during the subsequent thermal compression bonding process needs to be greater than or equal to a depth d1 of the recess rr, so as to compensate for a drop caused by the recess rr of the first bonding pad layer 112a. Herein, the depth d1 of the recess rr is defined as a distance between the deepest part of the recess rr and the first insulation layer 116a of the first bonding surface 100a. The distance Δd is defined as the maximum value of a displacement change of the surface of the first bonding pad layer 112a before and after the thermal compression bonding process.

In some embodiments, when the first bonding pad layer 112a and the circuit layer 112b are made of a same material, the distance Δd may be expressed by a following equation 1:

$$Δ d = Δ T ( d 2 * {α}_{1} ) + Δ T * d 3 ( {α}_{2} - {α}_{1} ) . \qquad Equation 1$$

In equation 1, ΔT is a temperature difference before and after the thermal compression bonding process, d2 is a total thickness of the first bonding pad layer 112a, the first expansion modulation layer 120 and the circuit layer 112b, d3 is a thickness of the first expansion modulation layer 120, α₁ is a coefficient of thermal expansion of the first bonding pad layer 112a, and α₂ is a coefficient of thermal expansion of the first expansion modulation layer 120. It may be seen that by appropriately selecting the thickness and coefficient of thermal expansion of the first expansion modulation layer 120, the recess rr of the first bonding pad layer 112a may be compensated, which helps with the subsequent bonding process.

In some embodiments, when designing the circuit layout, the first bonding pad 112ap may be treated as a center to draw a nine-square grid, and the first bonding pad 112ap is located at the center of the nine-square grid. An average coefficient of thermal expansion of the structure corresponding to the center position of the nine-square grid is basically equal to an average coefficient of thermal expansion of the structure corresponding to surrounding positions (i.e., the remaining eight positions in the nine-square grid except the center position) of the nine-square grid. The average coefficient of thermal expansion is calculated as ΣᵢVᵢ*αᵢ, where i is all the structures in the area (for example, including the first conductive layer 112, the first vias 114, the first insulation structure 116, the first expansion modulation layer 120, the first conductive pillars 140 and/or the first molding body 150, etc.), Vi is a volume fraction of i in this area, and ai is a coefficient of thermal expansion of i. Based on this, a configuration position and a size (such as thickness, etc.) of the first expansion modulation layer 120 may be configured so that the first expansion modulation layer 120 may compensate for the recess rr of the first bonding pad 112ap during the bonding process, but does not affect the flatness of a surrounding structure of the first bonding pad 112ap.

In some embodiments, the thickness d3 of the first expansion modulation layer 120 may be 0.1 to 0.4 times of a thickness d4 of the first bonding pad layer 112a. In some embodiments, the total thickness d2, thickness d3, and thickness d4 are average thicknesses.

Based on the above description, fabrication of the first structure 100′ may be roughly completed.

Referring to FIG. 8Q, the first structure 100′ and a second structure 200′ are provided. The second structure 200′ may have a similar structure to the first structure 100′ and may be formed through a similar process. However, the disclosure is not limited thereto. The second structure 200′ may have a different structure from the first structure 100′, but the second bonding surface 200a of the second structure 200′ needs to be provided with the second bonding pad layer 212a.

Referring to FIG. 8Q and FIG. 8R, the first structure 100′ and the second structure 200′ are bonded. For instance, the second bonding surface 200a of the second structure 200′ and the first bonding surface 100a of the first structure 100′ may be arrange face to face first. In this way, the first bonding pad layer 112a and the second bonding pad layer 212a are disposed correspondingly, and the first insulation structure 116 (or the first insulation layer 116a) of the first structure 100′ is in direct contact with the second insulation structure 216 of the second structure 200′. Next, a thermal compression bonding process is performed to cause the first bonding pad layer 112a and/or the second bonding pad layer 212a to expand due to heat, so that the first bonding pad layer 112a and the second bonding pad layer 212a are in direct contact to form the bonding layer 105. Specifically, since the first expansion modulation layer 120 is disposed between the first bonding pad layer 112a and the circuit layer 112b, during the thermal compression bonding process, the surface of the first bonding pad layer 12a may protrude a distance Δd in the vertical direction z due to the thermal expansion of the first expansion modulation layer 120, where the distance Δd is greater than or equal to the depth d1 of the recess rr. Similarly, the second expansion modulation layer 120 of the second structure 200′ is similar to the first expansion modulation layer 120, and the recess of the second bonding pad layer 212a may be compensated through the arrangement of the second expansion modulation layer 120, which helps with execution of the bonding process. Therefore, the first bonding pad layer 112a of the first structure 100′ may directly contact the second bonding pad layer 212a of the second structure 200′ during the thermal compression bonding process and implement metal-to-metal bonding. The first bonding pad layer 112a and the corresponding second bonding pad layer 212a thereby form into a conductive bonding structure. In this way, before the first structure 100′ and the second structure 200′ are bonded, the first bonding surface 100a and the second bonding surface 200a may be bonded directly without going through a planarization process, so that the process is simplified and the manufacturing costs are lowered.

In some embodiments, a temperature of the thermal compression bonding process is below 250° C.

In some embodiments, the distance Δd that the surface of the first bonding pad layer 112a protrudes in the vertical direction z due to the thermal expansion of the first expansion modulation layer 120 may be 1 to 1000 times of the depth d1 of the recess rr.

In some embodiments, during the thermal compression bonding process, the first expansion modulation layer 120 may extend toward the first bonding pad layer 112a and/or the circuit layer 112b due to thermal expansion.

In some embodiments, during the thermal compression bonding process, the surface of the first insulation structure 116 of the first structure 100′ may be in dielectric-to-dielectric bonding with the surface of the second insulation structure 216 of the second structure 200′. In this way, so the surface of the first insulation structure 116 and the surface of the second insulation structure 216 are still in contact with each other after the thermal compression bonding process, and the bonding strength between the first structure 100′ and the second structure 200′ is thus enhanced. However, the disclosure is not limited thereto. In other embodiments, as shown in FIG. 8R′, since the first bonding pad layer 112a and the second bonding pad layer 212a expand during the thermal compression bonding process, the first insulation structure 116 and the second insulation structure 216 that are originally in contact with each other are separated to form a gap g between the insulation structure 116 and the second insulation structure 216.

Referring back to FIG. 8R, the first molding body 150 of the first structure 100′ and the second molding body 250 of the second structure 200′ are respectively subjected to a planarization process (such as a chemical mechanical grinding process, a mechanical grinding process, or other suitable processes) to expose a back surface of the first chip 130 and the first conductive pillars 140 and a back surface of the second chip 230 and the second conductive pillars 240.

Referring to FIG. 8S, a heat sink 182 may be formed on the back surface of the first chip 130. In some embodiments, a top conductive layer (not shown, please refer to the top conductive layer 180 of FIG. 1) may be formed on the first molding body 150 and the first conductive pillar 140.

In this way, the fabrication of the first structure 100 may be roughly completed.

On the other hand, a third circuit layer 210′ may be formed on the second molding body 250. Formation of the third circuit layer 210′ may be similar to the formation method of the first circuit layer 110, which will not be repeated here. Next, conductive terminals 290 may be formed on the exposed third conductive layer 212′ of the third circuit layer 210′. The conductive terminals 290 may be in the form of a ball grid array (BGA), a land grid array (LGA), or other forms, which is not limited by the disclosure. In this way, the fabrication of the second structure 200 may be roughly completed.

In some embodiments, the inductor 170 shown in FIG. 4A to FIG. 4B, FIG. 5A to FIG. 5B, FIG. 6A to FIG. 6B or FIG. 7A to FIG. 7B may be formed during the process of forming the top conductive layer, the first conductive pillars 140, the first circuit structure 110, the second circuit structure 210, the second conductive pillars 240 and/or the third circuit layer 210′.

Based on the above, the fabrication of the stacked substrate structure 10 may be roughly completed.

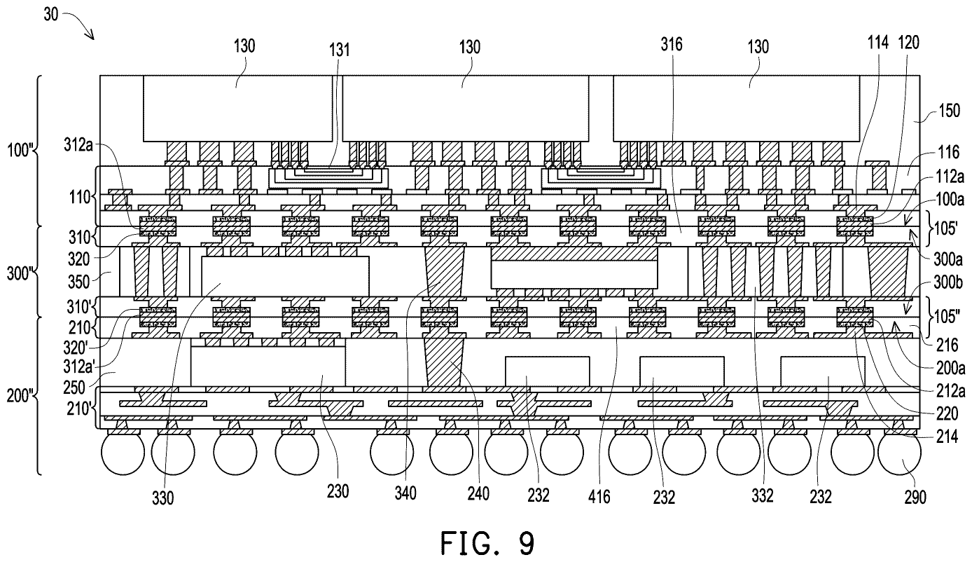

FIG. 9 is a schematic cross-sectional view of a stacked substrate structure according to an embodiment of the disclosure. It must be noted here that the embodiment of FIG. 9 follows the component referential numbers and part of the content of the embodiment of FIG. 1, where the same or similar referential numbers are used to represent the same or similar elements, and the description of the same technical content is omitted. For description of the omitted parts, reference may be made to the foregoing embodiments and details thereof are not repeated herein.

Referring to FIG. 9, a stacked substrate structure 30 includes a first structure 100″, a second structure 200″ and a third structure 300″. The third structure 300″ is located between the first structure 100″ and the second structure 200″. The first structure 100 has a first bonding surface 100a, the second structure 200 has a second bonding surface 200a, and the third structure 300″ has a third bonding surface 300a and a fourth bonding surface 300b. The third bonding surface 300a and the fourth bonding surface 300b are opposite to each other. The first bonding surface 100a of the first structure 100 faces the third bonding surface 300a of the third structure 300″. The second bonding surface 200a of the second structure 200 faces the fourth bonding surface 300b of the third structure 300″.

The first structure 100″ may include a first circuit structure 110, a first chip 130 and a first molding body 150, which is similar to the first structure 100 of the previous embodiment. The first circuit structure 110 may include a first insulation structure 116, a plurality of first conductive layers 112 (including a first bonding pad layer 112a located on the first bonding surface 100a), a plurality of first vias 114 and a first expansion modulation layer 120. The first expansion modulation layer 120 may be located between the first bonding pad layer 112a and the first vias 114.

The second structure 200″ may include a second circuit structure 210, a third circuit structure 210′, a second chip 230, a second conductive pillar 240, a second molding body 250 and conductive terminals 290, which is similar to the second structure 200 of the previous embodiment. The second circuit structure 210 may include a second insulation structure 216, a plurality of second conductive layers 212 (including a second bonding pad layer 212a on the second bonding surface 200a), a plurality of second vias 214 and a second expansion modulation layer 220. The second expansion modulation layer 220 may be located between the second bonding pad layer 212a and the second via 214.

The third structure 300″ may include a fourth circuit structure 310, a fifth circuit structure 310′, a third chip 330, a third conductive pillar 340 and a third molding body 350. The third molding body 350, the third chip 330 and the third conductive pillar 340 are disposed between the fourth circuit structure 310 and the fifth circuit structure 310′. The fourth circuit structure 310 is disposed near the third bonding surface 300a, and the fifth circuit structure 310′ is disposed near the fourth bonding surface 300b. The third chip 330 and the third conductive pillar 340 are disposed in the third molding body 350 and may be electrically connected to the fourth circuit structure 310 and/or the fifth circuit structure 310′.

In some embodiments, the fourth circuit structure 310 may include a third bonding pad layer 312a located on the third bonding surface 300a, and the third bonding pad layer 312a may directly contact and connect with the first bonding pad layer 112a to form a bonding layer 105′. In some embodiments, the fourth circuit structure 310 further includes a third expansion modulation layer 320 disposed below the third bonding pad layer 312a (i.e., on a side of the third bonding pad layer 312a away from the third bonding surface 300a). In this way, the first bonding pad layer 112a and the third bonding pad layer 312a are located between the first expansion modulation layer 120 and the third expansion modulation layer 320 to facilitate bonding between the third structure 300″ and the first structure 100″.

In some embodiments, the fifth circuit structure 310′ may include a fourth bonding pad layer 312a′ located on the fourth bonding surface 300b, and the fourth bonding pad layer 312a′ may be in direct contact with the second bonding pad layer 212a to form a bonding layer 105″. In some embodiments, the fifth circuit structure 310′ further includes a fourth expansion modulation layer 320′ disposed above the fourth bonding pad layer 312a′ (i.e., on a side of the fourth bonding pad layer 312a′ away from the fourth bonding surface 300b). The second bonding pad layer 212a and the fourth bonding pad layer 312a′ are thereby located between the second expansion modulation layer 220 and the fourth expansion modulation layer 320′ to facilitate bonding between the third structure 300″ and the second structure 200″.

In some embodiments, the first circuit structure 110 of the first structure 100″ may be used as a chip connection layer, so that the second structure 200″ and the third structure 300″ may be electrically connected to the first chip 130 through the first circuit structure 110. In some embodiments, the first circuit structure 110 may further include a bridge chip 131 disposed in the first insulation structure 116, so that two adjacent first chips 130 may be electrically connected through the bridge chip 131.

In some embodiments, the second structure 200″ may further include a device 232, and the third structure 300″ may further include a device 332. The device 232 may be disposed on the third circuit structure 210′ and electrically connected to the third circuit structure 210′. The device 332 may be disposed in the third molding body 350 and may be electrically connected to the fourth circuit structure 310 and/or the fifth circuit structure 310′. The device 232 and the device 332 may respectively include sensors, optical communication components (such as optical waveguides, etc.), passive components, or other devices.

In some embodiments, the first structure 100″, the second structure 200″ and/or the third structure 300″ may include the capacitor 160 as shown in FIG. 3A to FIG. 3C or the capacitor 170 as shown in FIG. 4A to FIG. 4B, FIG. 5A to FIG. 5B, FIG. 6A to FIG. 6B, and FIG. 7A to FIG. 7B, but the disclosure is not limited thereto.

FIG. 9 schematically shows that the stacked substrate structure 30 includes three stacked structures, but this is not intended to limit the disclosure. The number of the stacked structures may be adjusted according to actual needs.

In summary, the stacked substrate structure of the disclosure is formed by bonding multiple stacked structures to each other. By arranging an expansion modulation layer between the bonding pads and the circuit layer of the stacked structure, the bonding surface of the stacked structure may be directly connected to another stacked structure. The manufacturing process is thereby simplified and the manufacturing costs are lowered. Moreover, direct bonding of multiple stacked structures may shorten a signal transmission distance and increase a signal transmission speed.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A stacked substrate structure, comprising:
a first structure having a first bonding surface, wherein the first structure comprises:
a first circuit structure, comprising:
a plurality of first conductive layers stacked in a vertical direction; and
a first expansion modulation layer disposed between the plurality of adjacent first conductive layers, wherein a coefficient of thermal expansion of the first expansion modulation layer is greater than a coefficient of thermal expansion of the plurality of first conductive layers; and
a second structure having a second bonding surface, wherein the second bonding surface of the second structure faces the first bonding surface of the first structure.

2. The stacked substrate structure according to claim 1, wherein the plurality of first conductive layers comprise a first bonding pad layer, and the first bonding pad layer is located on the first bonding surface,
wherein the second structure comprises a second bonding pad layer located on the second bonding surface, and the second bonding pad layer is in direct contact with the first bonding pad layer.

3. The stacked substrate structure according to claim 2, wherein a material of the first bonding pad layer and the second bonding pad layer comprises nanocrystalline copper, nanotwinned copper, or nanocrystalline nanotwinned copper.

4. The stacked substrate structure according to claim 1, wherein the first circuit structure further comprises:
a plurality of first vias disposed between the adjacent plurality of first conductive layers; and
a first insulation structure, wherein the plurality of first conductive layers and the plurality of first vias are disposed in the first insulation structure, and a material of the first insulation structure comprises polyimide, polybenzoxazole, benzocyclobutene, or silicon oxide.

5. The stacked substrate structure according to claim 4, wherein the first expansion modulation layer is located in part of the plurality of first vias.

6. The stacked substrate structure according to claim 4, wherein the first expansion modulation layer is located between one of the plurality of first vias and a corresponding one of the plurality of first conductive layers.

7. The stacked substrate structure according to claim 4, wherein part of the plurality of first vias comprise a metal-insulator-metal structure to form a capacitor.

8. The stacked substrate structure according to claim 2, wherein the second structure further comprises a second expansion modulation layer, the second expansion modulation layer is disposed on a side of the second bonding pad layer away from the second bonding surface, and a coefficient of thermal expansion of the second expansion modulation layer is greater than a coefficient of thermal expansion of the second bonding pad layer,
wherein the first bonding pad layer and the second bonding pad layer are located between the first expansion modulation layer and the second expansion modulation layer.

9. The stacked substrate structure according to claim 4, wherein the first structure further comprises:
a first chip disposed on the first circuit structure and electrically connected to the first circuit structure;
a first molding body disposed on the first circuit structure and encapsulating the first chip;
a first conductive pillar disposed in the first molding body and electrically connected to the first circuit structure; and
a top conductive layer disposed on the first molding body and the first conductive pillar and electrically connected to the first conductive pillar.

10. The stacked substrate structure according to claim 9, wherein the second structure includes:
a second molding body;
a second circuit structure disposed on the second molding body, wherein the second circuit structure comprises the second bonding pad layer;
a third circuit structure disposed on a side of the second molding body relative to the second circuit structure;
a second conductive pillar disposed in the second molding body and electrically connected to the second circuit structure and the third circuit structure,
wherein the first chip is electrically connected to the third circuit structure through the first circuit structure, the second circuit structure, and the second conductive pillar.

11. The stacked substrate structure according to claim 10, further comprising an inductor, wherein the inductor comprises:
a top circuit layer comprising a plurality of top circuit segments formed by a portion of the top conductive layer;
a bottom circuit layer comprising a plurality of bottom circuit segments formed by a portion of the third conductive layer of the third circuit structure; and
a plurality of vertical connectors located between the plurality of top circuit segments and the plurality of bottom circuit segments, wherein the plurality of vertical connectors comprise a portion of the first conductive pillar, a portions of the plurality of first vias, a portion of the first bonding pad layer, a portion of the second bonding pad layer, and a portion of the second conductive pillar stacked in the vertical direction.

12. A manufacturing method of a stacked substrate structure, comprising:
providing a first structure, wherein the first structure has a first bonding surface, and the first structure comprises:
a first circuit structure, comprising:
a plurality of first conductive layers stacked in a vertical direction, wherein the plurality of first conductive layers comprise a first bonding pad layer, and the first bonding pad layer is located on the first bonding surface; and
a first expansion modulation layer, disposed between the plurality of adjacent first conductive layers, wherein a coefficient of thermal expansion of the first expansion modulation layer is greater than a coefficient of thermal expansion of the plurality of first conductive layers;
providing a second structure, wherein the second structure has a second bonding surface, and the second structure comprises a second bonding pad layer located on the second bonding surface; and
bonding the first structure and the second structure through a thermal compression bonding process, wherein a first bonding pad layer and the second bonding pad layer are in direct contact and are connected.

13. The manufacturing method of the stacked substrate structure according to claim 12, wherein before the first structure and the second structure are bonded, the first bonding pad layer of the first structure has a recess,
during the thermal compression bonding process, a distance Δd of displacement of a surface of the first bonding pad layer in the vertical direction due to thermal expansion of the first expansion modulation layer is greater than or equal to a depth of the recess, so that the first bonding pad layer and the second bonding pad layer are in direct contact.

14. The manufacturing method of the stacked substrate structure according to claim 13, wherein the distance Δd is represented by a following equation 1,
$$Δ d = Δ T ( d 2 * {α}_{1} ) + Δ T * d 3 ( {α}_{2} - {α}_{1} ) , \qquad [ equation 1 ]$$
in the equation 1, Δd is the distance, ΔT is a temperature difference before and after the thermal compression bonding process, d2 is a total thickness of the first bonding pad layer, the first expansion modulation layer, and the plurality of first conductive layers, d3 is a thickness of the first expansion modulation layer, α₁ is a coefficient of thermal expansion of the first bonding pad layer, and α₂ is the coefficient of thermal expansion of the first expansion modulation layer.

15. The manufacturing method of the stacked substrate structure according to claim 13, wherein the distance Δd is 1 to 1,000 times of the depth of the recess.

16. The manufacturing method of the stacked substrate structure according to claim 13, wherein the step of forming the first structure comprises:
forming a seed layer on a carrier board;
forming the first bonding pad layer on the seed layer;
forming a first insulation layer on the first bonding pad layer, wherein the first insulation layer has a plurality of openings to expose a portion of the first bonding pad layer;
forming the first expansion modulation layer in the plurality of openings;
forming the first conductive layer on the first expansion modulation layer and the first insulation layer; and
peeling off the carrier board and removing the seed layer to expose the first bonding pad layer and the first insulation layer.

17. The manufacturing method of the stacked substrate structure according to claim 13, wherein the step of bonding the first structure and the second structure comprises:
arranging the second bonding surface and the first bonding surface face to face, so that the first bonding pad layer and the second bonding pad layer are disposed correspondingly, and a first insulation structure of the first bonding surface is in direct contact with a second insulation structure of the second bonding surface; and
performing the thermal compression bonding process, wherein the first bonding pad layer and the second bonding pad layer are thermally expanded, so that the first bonding pad layer and the second bonding pad layer are in direct contact and implement metal-to-metal bonding.

18. The manufacturing method of the stacked substrate structure according to claim 17, wherein after the thermal compression bonding process is performed, the first insulation structure is in direct contact with the second insulation structure.

19. The manufacturing method of the stacked substrate structure according to claim 17, wherein after the thermal compression bonding process is performed, the first insulation structure and the second insulation structure are spaced apart from each other.

20. The manufacturing method of the stacked substrate structure according to claim 13, wherein a temperature of the thermal compression bonding process is below 250° C.
